(19) United States
(12) Patent Application Publication
(10) Pub. No.: US 2007/0229317 A1
(43) Pub. Date: Oct. 4, 2007

(54) SEQUENCING OF CHARACTER ASSIGNMENT FOR KEYPADS

(76) Inventor: Kai Chuang, Boston, MA (US)

Correspondence Address: Kai Chuang, 81 Mt. Vernon St. #6, Boston, MA, 02108, US

(21) Appl. No.: 11/682,251

(22) Filed: Mar. 5, 2007

Related U.S. Application Data
(60) Provisional application No. 60/743,553, filed on Mar. 18, 2006.

(51) Int. Cl. H03M 11/00

(52) U.S. Cl. 341/22

(57) ABSTRACT

A ten-key telephone keypad where the sequence of characters assigned to each number on said keypad corresponds with the frequencies of occurrence for said characters relative to one another.

### CROSS-REFERENCE TO RELATED APPLICATIONS

This application claims the benefit of PPA Ser. No. 60/743,553, filed 18 Mar. 2006 by the present inventor, which is incorporated by reference.

### FEDERALLY SPONSORED RESEARCH

Not Applicable

### SEQUENCE LISTING OR PROGRAM

Not Applicable

### BACKGROUND

1. Field of Invention

This invention relates to ten-key telephone keypads, specifically to the sequencing of characters.

2. Prior Art

The proliferation of portable devices (e.g. mobile phones, convergence devices) and personal communication applications (e.g. email, instant message, text message) has resulted in the use of the traditional ten-key telephone keypad, comprised of buttons 0-9, for high volume text entry. Unfortunately, the physical limitation of using only ten buttons to enter characters (e.g. k, c) means it can take a long time to enter text. In particular, an alphabetical assignment of characters to numbers is inefficient (e.g. pressing the 3 button two times to enter the letter e even though e is the most used character in English). Additionally, when considering more keystrokes likely result in more errors, using a traditional telephone keypad to enter text leaves much to be desired.

Nevertheless, the ten-key telephone keypad design has been in place for a long time. People understand and are familiar with using a ten-key keypad to enter text characters. Additionally, many applications (e.g. voicemail, call center) rely on the ten-key telephone keypad's pairing of characters with numbers (e.g. characters a, b, and c with number 2) to function properly. For example, the USPTO Strategy Targeting Organized Piracy (STOP) hotline is: 1-866-999-HALT. If characters H, A, L, and T were assigned to different numbers, the wrong telephone number would be dialed.

Various approaches such as those described in U.S. Pat. Nos. 6,847,706, 6,885,317, and 5,818,437 have been developed to improve the efficiency of text entry; however, they involve adding more buttons or changing the ten-key telephone keypad's pairing of characters with numbers. As a result, these approaches create new challenges that require people to learn new keys or breaking application that rely on the traditional pairing of characters with numbers.

### DRAWINGS

FIG. 1 is a view of a first embodiment of my invention.

### DETAILED DESCRIPTION

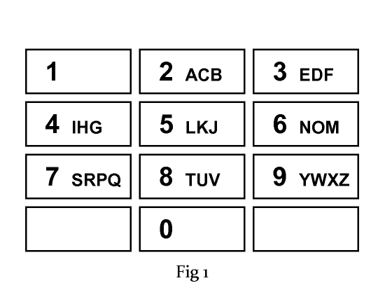

### First Embodiment—FIG. 1

An embodiment of this invention increases the efficiency of text entry using a ten-key telephone keypad. By applying statistical analyses to identify the most frequently occurring characters in the English language, it's possible to rearrange the sequence of alphabetical characters for each number on said keypad.

### OPERATION

### First Embodiment—FIG. 1

For example, the letter e is the most frequently used English character. Therefore, it is positioned first in the character sequence of the number 3 on a ten-key telephone keypad. Similarly, the character s is positioned first in the character sequence of the number 7 because more English words begin with s than any other letter. Correspondingly, a single press of buttons 3 and 7 of this embodiment will result in the appearance of letters e and s, respectively.

When compared to using devices based on the traditional telephone keypad design, this embodiment can substantially reduce the time to enter text (measured by number of key strokes).

### CONCLUSION, RAMIFICATIONS, AND SCOPE

Accordingly, the reader will see that, according to one embodiment of the invention, I have provided a means to increase the efficiency of entering text using a ten-key telephone keypad without changing the pairing of characters with numbers of said keypad. By doing so, it becomes possible to compose text messages more quickly, more efficiently, and more accurately.

Although the description above contains many specificities, these should not be construed as limiting the scope of the embodiment but as merely providing illustrations of some of the presently preferred embodiment. For example, the embodiment could be implemented by effecting character assignment at the hardware level or through software such as a texting program, etc.

Thus, the scope of the embodiment should be determined by the appended claims and their legal equivalents, rather than by the examples given.

1. A hardware or software keypad apparatus comprising a plurality of buttons wherein a subset of said buttons corresponds to numbers 0-9 and a sequence of ACB corresponding to number 2.

2. The keypad of claim 1, further comprising a sequence EDF corresponding to number 3.

3. The keypad of claim 1, further comprising a sequence IHG corresponding to number 4.

4. The keypad of claim 1, further comprising a sequence LKJ corresponding to number 5.

5. The keypad of claim 1, further comprising a sequence NOM corresponding to number 6.

6. The keypad of claim 1, further comprising a sequence SRPQ corresponding to number 7.

7. The keypad of claim 1, further comprising a sequence YWXZ corresponding to number 9.
